(19) United States
(12) Patent Application Publication
(10) Pub. No.: US 2024/0149468 A1
(43) Pub. Date: May 9, 2024

(54) COLLET REPLACEMENT MECHANISM

(71) Applicant: TORAY ENGINEERING CO., LTD., Tokyo (JP)

(72) Inventors: Hiroto TANAKA, Otsu-shi, Shiga (JP); Kenji HAMAKAWA, Otsu-shi, Shiga (JP); Tomonori KAWAMURA, Otsu-shi, Shiga (JP)

(21) Appl. No.: 18/549,824

(22) PCT Filed: Dec. 15, 2021
(86) PCT No.: PCT/JP2021/046229

§ 371 Date: Sep. 8, 2023

(30) Foreign Application Priority Data
Mar. 31, 2021 (JP) 2021-059735

(51) Int. Cl. B25J 15/04; B25J 15/06

(52) U.S. Cl. CPC B25J 15/0441; B25J 15/0616

(57) ABSTRACT

A collet replacement mechanism for replacing a collet of a pickup tool that is configured to pick up chip components by suction using the collet comprises an attachment configured to hold the collet on a bottom surface thereof, an attachment holder disposed at a lower part of the pickup tool and configured to hold an upper part of the attachment by magnetic force, and an attachment storage unit having a guide that is configured to latch the attachment to store the attachment, the attachment being detachable from the attachment holder in a state of being latched to the guide.

### CROSS-REFERENCE TO RELATED APPLICATIONS

This application is a U.S. National stage of International Application No. PCT/JP2021/046229 filed on Dec. 15, 2021. This application claims priority to Japanese Patent Application No. 2021-059735 filed on Mar. 31, 2021 with Japan Patent Office. The entire disclosure of Japanese Patent Application No. 2021-059736 is hereby incorporated herein by reference.

### BACKGROUND

### Field of the Invention

The present invention relates to a collet replacement mechanism for replacing the collet of a pickup tool that picks up chip components with a collet.

### Background Information

In providing a semiconductor chip or other such chip component to a bonder, a mounter, or another such mounting device, there is a supply mode in which the component is picked up from a state of being adhesively bonded to a dicing tape. In this supply mode, chip components are picked up one at a time from among a plurality of chip components on the dicing tape.

That is, from the state in which a needle 11 and a collet 21 are aligned with a chip component C, which is what is to be picked up from among a plurality of chip components C adhesively bonded to a dicing tape S as shown in FIG. 17A, the needle 11 thrusts up the chip component C from the dicing tape S side as shown in FIG. 17B, and the collet 21 chucks the chip component C in a state in which the chip component C is in close contact with the collet 21 as shown in FIG. 17C, the result being that the chip component C that had been adhesively bonded to the dicing tape S is picked up with the collet 21 as shown in FIG. 17D (for example, Japanese Patent Application Publication No. 2017-130499 (Patent Literature 1)).

### SUMMARY

Chip components such as semiconductor chips are becoming thinner, and if a collet that does not match the size of the chip components is used, the chip components may be damaged or pickup errors will occur frequently.

On the other hand, there are a growing number of cases in which chip components of varying sizes are mounted on a single substrate, which means that the collet needs to be replaced more often.

However, since collet replacement has been performed manually in the past, the time and labor required for collet replacement adversely affect productivity.

Various collet replacement mechanisms have been proposed for use in such situations (for example, Japanese Patent Application Publication No. 2018-206843 (Patent Literature 2)). However, most such cases entail a complicated configuration or operation.

One object is to provide a collet replacement mechanism with which replacement of the collet of a pickup tool that uses a collet to pick up chip components can be performed with a simple configuration and in a short period of time.

To solve the above problem, according to a first aspect, a collet replacement mechanism for replacing the collet of a pickup tool that picks up chip components by suction using a collet is provided that comprises: an attachment that holds the collet on the bottom surface, an attachment holder that is disposed at the lower part of the pickup tool and holds the upper part of the attachment, and an attachment storage unit that stores the attachment by latching it to a guide, wherein the attachment holder has a function of holding the attachment by magnetic force, and the attachment is detached from the attachment holder in a state of being latched to the guide.

According to a second aspect, a collet replacement mechanism for replacing the collet of a pickup tool that picks up chip components by suction using a collet is provided that comprises: an attachment that holds the collet on the bottom surface, an attachment holder that is disposed at the lower part of the pickup tool and holds the upper part of the attachment, and an attachment storage unit that can store the attachment and can slide the attachment along a guide, wherein the attachment holder has a function of holding the attachment by magnetic force, and the attachment is detached by being moved in a direction different from the sliding direction with respect to the guide of the attachment storage unit.

According to a third aspect, the collet replacement mechanism according to the first aspect or the second aspect is configured such that the magnetic force with which the attachment holder holds the attachment is strong enough that the attachment holder will not come off when a chip component is picked up, whereas the strength of the guide restricting the vertical movement of the attachment makes it possible to remove the attachment from the attachment holder by lifting up the pickup tool.

According to a fourth aspect, the collet replacement mechanism according to any one of the first to the third aspects is configured such that the attachment storage unit is provided with a slide prevention means for suppressing positional displacement of the attachment.

According to a fifth aspect, the collet replacement mechanism according to the fourth aspect is configured such that the guide is provided with an elastic body that makes contact with the side surface of the attachment, and serves as the slide prevention means.

According to a sixth aspect, the collet replacement mechanism according to the fourth aspect is configured such that a magnet is used as the slide prevention means.

According to a seventh aspect, the collet replacement mechanism according to the fourth aspect is configured such that a groove is provided on the upper surface of the guide as the slide prevention means.

With the present disclosure, replacement of the collet of a pickup tool that uses a collet to pick up chip components can be performed with a simple configuration and in a short period of time.

### BRIEF DESCRIPTION OF THE DRAWINGS

FIGS. 1A and 1B are schematic diagrams of a collet replacement mechanism according to an embodiment of the present disclosure;

FIGS. 2A, 2B, 2C and 2D are four diagrams illustrating an attachment in the embodiment of the present disclosure, with FIG. 2A being a top view, FIG. 2B being a front view, FIG. 2C being a side view, and FIG. 2D being a bottom view;

FIG. 3 is a diagram illustrating a layout example of an attachment storage unit according to the embodiment of the present disclosure;

FIG. 4 illustrates the operation of the collet replacement mechanism according to the embodiment of the present disclosure, and is a side view for illustrating a state in which the heights of the attachment and the guide are adjusted;

FIGS. 5A, 5B and 5C are top views illustrating the operation of storing an attachment in the attachment storage unit of the collet replacement mechanism according to the embodiment of the present disclosure, with FIG. 5A showing a state in which the guide and the attachment are aligned in the width direction, FIG. 5B showing a state in which the attachment is slid along the guide and FIG. 5C showing a state in which the attachment is disposed in a specific storage position;

FIGS. 6A, 6B, 6C and 6D are front views illustrating the process of removing an attachment disposed in the attachment storage unit from the pickup tool in the operation of the collet replacement mechanism according to the embodiment of the present disclosure, with FIG. 6A showing a state in which the attachment can be slide along the guide, FIG. 6B showing a state in which the upward movement of the attachment is restricted, FIG. 6C showing a state in which the pickup tool is further raised while the upward movement of the attachment is restricted, and FIG. 6D showing a state in which the attachment has been removed from the pickup tool.

FIG. 7 is a front view illustrating the size relationship between the attachment and the guide;

FIG. 8 is a top view showing a state in which an attachment removal operation is commenced with the collet replacement mechanism according to the embodiment of the present disclosure;

FIGS. 9A, 9B, 9C and 9D are front views illustrating the operation of putting an attachment in the attachment storage unit in a slidable state with the collet replacement mechanism according to the embodiment of the present disclosure, with FIG. 9A showing a state in which the pickup tool is disposed on the attachment, FIG. 9B showing a state in which the pickup tool is being lowered to hold the attachment, FIG. 9C showing a state in which the pickup tool holds the attachment, and FIG. 9D showing a state in which the height position of the pickup tool has been adjusted so that the attachment can slide without touching the guide;

FIGS. 10A, 10B and 10C are top views illustrating the operation of removing an attachment from the attachment storage unit in the collet replacement mechanism according to the embodiment of the present disclosure, with FIG. 10A showing a state in which an attachment in the storage position is at a height that allows sliding, FIG. 10B showing a state in which the attachment is slid in the removal direction, and FIG. 10C showing a state in which the attachment has been removed from the attachment storage unit;

FIG. 11 is a top view showing an example in which an elastic body is provided to the attachment storage unit as a slide prevention means for suppressing displacement of the attachment in the collet replacement mechanism according to an embodiment of the present disclosure;

FIGS. 12A and 12B are front views illustrating the operation in an example of using an elastic body as the slide prevention means, with FIG. 12A showing a state in which the attachment is held by the pickup tool, and FIG. 12B showing a state in which the attachment has been removed from the pickup tool;

FIG. 13 is a top view showing an example in which an elastic body is provided to the attachment storage unit as a slide prevention means for suppressing displacement of the attachment in the collet replacement mechanism according to an embodiment of the present disclosure;

FIGS. 14A, 14B and 14C are side views illustrating an example in which a groove is made in the upper surface of the guide to provide the attachment storage unit with a slide prevention means for suppressing displacement of the attachment in the collet replacement mechanism according to an embodiment of the present disclosure, with FIG. 14A showing a state in which the height of the attachment has been adjusted, FIG. 14B showing a state in which the attachment slides along the guide, and FIG. 14C showing a state in which the attachment is disposed in the storage position;

FIG. 15 is a side view illustrating the size relationship between the attachment and the guide in an example in which a groove is made in the guide;

FIG. 16 is a front view showing a modification example in which the shapes of the attachment and guide have been changed in the collet replacement mechanism according to an embodiment of the present disclosure; and

FIGS. 17A, 17B, 17C and 17D illustrate the operation of picking up a chip component, with FIG. 17A showing the initial state, FIG. 17B showing a state in which the chip component is in the process of being thrust up, FIG. 17C showing a state in which the chip component has been thrust up to the height of the collet, and FIG. 17D showing a state in which the collet holds the chip component by suction.

### DETAILED DESCRIPTION OF EMBODIMENTS

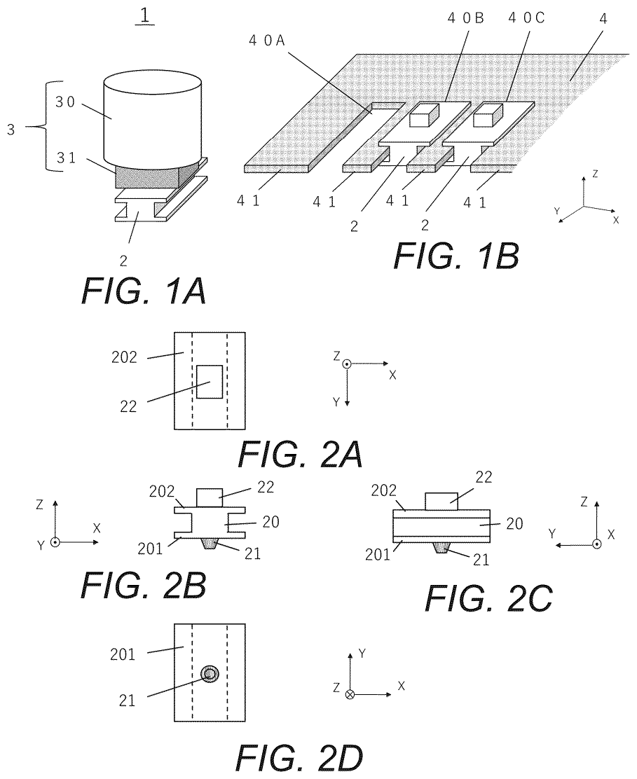

An embodiment of the present disclosure will be described with reference to the drawings. FIGS. 1A and 1B are schematic diagrams of a collet replacement mechanism according to an embodiment of the present disclosure.

A collet replacement mechanism 1 is used to replace the collet of a pickup tool 3 for picking up chip components, and is formed by an attachment 2 and an attachment storage unit 4. The pickup tool 3 has an attachment holder 31 that holds the attachment 2 under the pickup head 30.

The attachment 2 in this embodiment has the configuration shown in four views in FIGS. 2A, 2B, 2C and 2D. That is, it is made up of an attachment main body 20 having a lower wide portion 201 and an upper wide portion 202, a collet 21, and a tenon 22. With this configuration, the collet 21 is replaced by replacing the attachment 2.

Here, the collet 21 is made of a material such as rubber having elasticity so as to fit snugly against the chip component C to be picked up. An opening for applying suction to the chip component is provided in the center part, and a reduced pressure channel (not shown) is provided from this opening and through the attachment main body 20 and communicates with the reduced pressure channel of the pickup tool 30. The tenon 22 is inserted into a mortise provided in the attachment holder 31 and fixed. Furthermore, at least one of the attachment main body 20 and the tenon 22 is made of a magnetic material, and the attachment holder 31 is provided with a magnet, so that the attachment 2 is held by magnetic force when mated with the attachment holder 31. Also, the tenon 22 suppresses displacement of the attachment 2 in the rotational direction.

The pickup tool 3 can be moved up and down by a drive unit (not shown) and its position can be controlled at an accuracy of within 20 μm. Also, the pickup tool 3 may have an angle control function in the direction of rotation around the vertical direction (Z direction). As discussed above, the pickup holder 31 attracts the attachment 2 by magnetic force, and while an electromagnet may be used to generate the magnetic force, a permanent magnet is preferable in that no wiring is needed and the configuration is simpler.

The attachment storage unit 4 stores a plurality of attachments 2, and when the upper wide portion 202 of an attachment 2 catches one of the storage spaces 40 (40A, 40B, 40C, . . . ) formed by guides 41 disposed in parallel and spaced apart, the result is a stored state. That is, a storage space 40 is wider than the trunk of the attachment main body 20 and narrower than the upper wide portion 202 (and the lower wide portion 201).

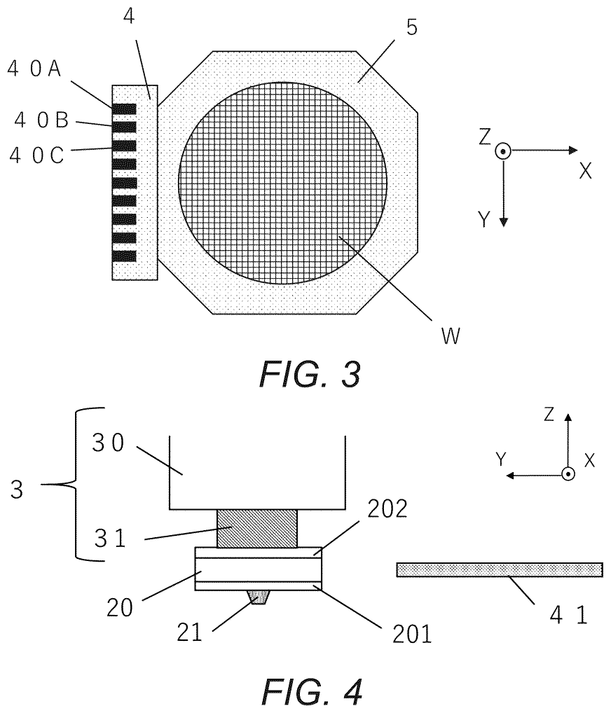

While the pickup tool 3 is able to move up and down, the attachment storage unit 4 moves within the horizontal plane (in the XY plane). A dedicated drive unit may be used for this horizontal movement, but as shown in FIG. 3, attaching to a wafer table 5 that holds a diced wafer W will allow for movement in the in-plane direction and positional adjustment.

The operation of the collet replacement mechanism of the present disclosure will now be described. First, the operation of storing an attachment 2 in the storage space 40A from a state in which the attachment 2 is held by the pickup tool 3 as shown in FIGS. 1A and 1B will be described.

The drive unit of the pickup tool 3 and the drive unit of the attachment storage unit 4 are connected to a control unit (not shown), and a series of operations is carried out according to signals from the control unit.

FIG. 4 is a side view showing how the height position of the attachment 2 is adjusted, in which the height of the pickup tool 3 is set so as to match the height of the attachment 2 to the guide 41. That is, in this state, the lower wide portion 201 is disposed lower than the guide 41, and the upper wide portion 202 is disposed higher.

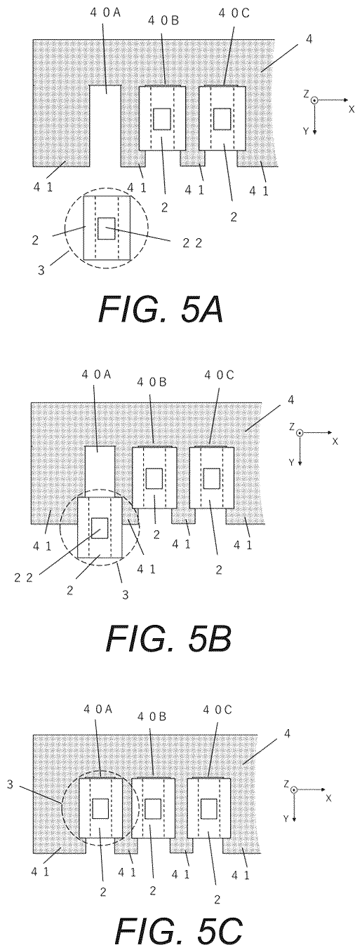

FIGS. 5A, 5B and 5C are top views showing how the attachment 2 is stored in the storage space 40A when the height of the attachment 2 has been adjusted. FIG. 5A shows a state in which the position of the attachment storage unit 4 is adjusted so that the attachment 2 is positioned so as to be insertable into the storage space 40A. After this positioning, the attachment storage unit 4 is moved so as to slide the guide 41 along the attachment 2 (FIG. 5B), and movement of the attachment storage unit 4 is stopped once the attachment 2 reaches a specific location in the storage space 40A (FIG. 5C).

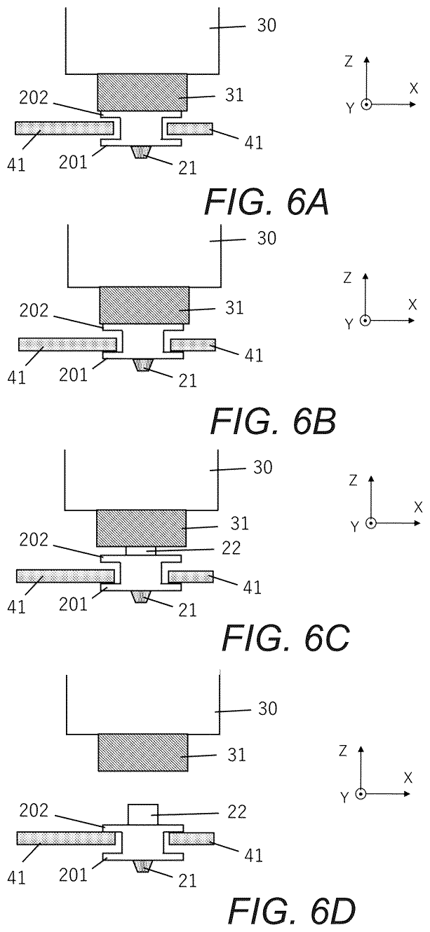

FIGS. 6A, 6B, 6C and 6D are front views showing how the attachment 2 is removed from (the attachment holder 31 of) the pickup tool 3 from the state in FIG. 5C. The state in FIG. 6A is immediately after the slide movement shown in FIG. 5C. The lower wide portion 201 is lower than the guide 41, and the upper wide portion 202 is higher. When the pickup tool 3 is raised from this state, the lower wide portion 201 catches on the guide 41 because the lower wide portion 201 is wider than the storage space 40A as shown in FIG. 6B. In this state, if the strength at which the guide 41 prevents the attachment 2 from rising exceeds the magnetic force with which the attachment holder 31 holds the attachment 2, the attachment holder 31 will move away from the attachment 2 as the pickup tool 3 rises, as shown in FIG. 6C. Finally, when the attachment holder 31 is removed from the attachment 2, the upper wide portion 202 catches on the guide 41 as shown in FIG. 6D, and the attachment 2 is disposed in the specified location of the storage space 40A.

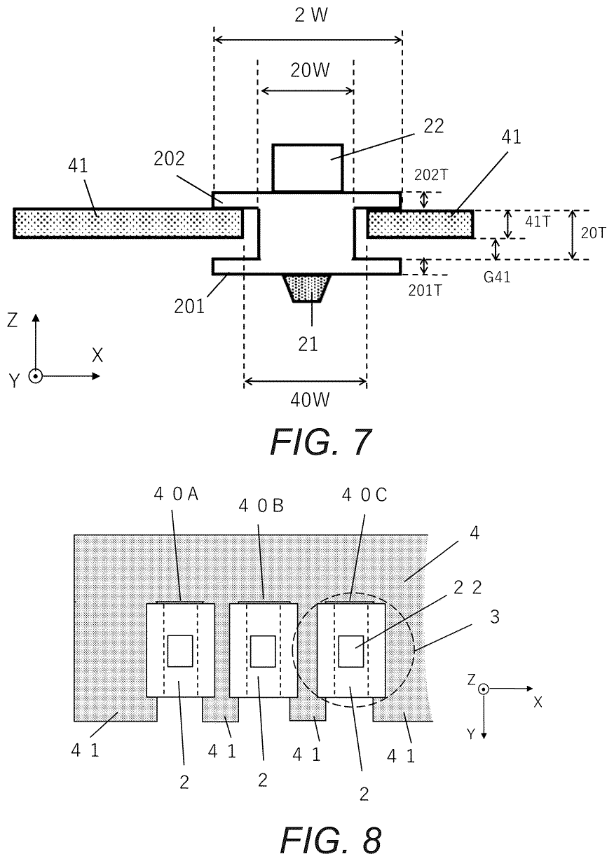

FIG. 7 shows the dimensions of the attachment 2 and the guide 41. As described above, the width 2W of the upper wide portion 202 must be greater than the storage space width 40W, but the trunk width 20W of the attachment 2 must be smaller than the storage space width 40W. The sliding movement will be hindered if the difference is too small, but it is also undesirable for the difference to be too large, with a bias in the width direction, because the upper wide portion 202 may come out. More specifically, the difference between the trunk width 20W of the attachment 2 and the storage space width 40W is preferably about 100 μm or more and 200 μm or less. This can also be said to be an appropriate range because the positional accuracy of a drive mechanism used in precision equipment such as the pickup tool and the attachment storage unit is 20 μm or less. Similarly, the difference between the thickness 20T of the attachment 2 (=the gap between the lower wide portion 201 and the upper wide portion 202) and the thickness 41T of the guide 41 is preferably about 100 μm or more and 200 μm or less.

FIGS. 8 to 10C illustrate how the pickup tool 3 puts the attachment 2 in the storage space 40C into a usable state (for the pickup operation).

First, FIG. 8 is a top view of a state in which the pickup tool 30 is positioned in the horizontal direction above the attachment 2 stored in the storage space 40C.

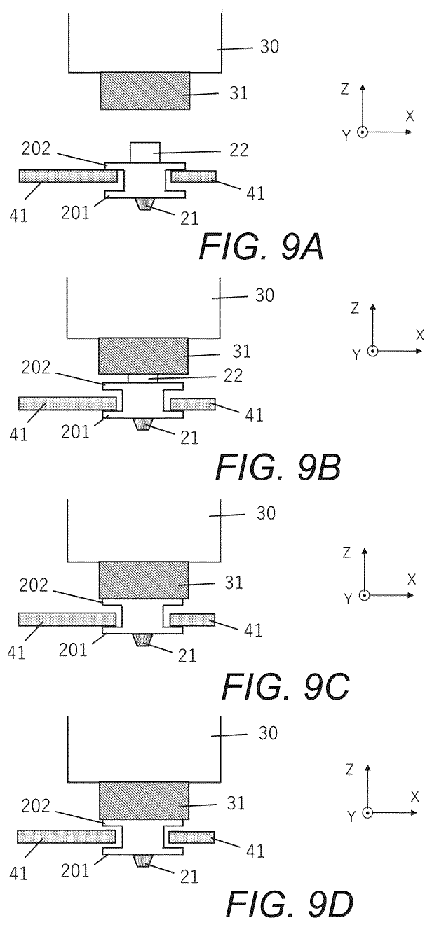

FIGS. 9A, 9B, 9C and 9D are front views of the state after the pickup tool has been disposed on the upper part of the attachment 2. FIG. 9A shows a state in which the pickup tool 3 is lowered closer to the attachment 2 after horizontal positioning. After this, the pickup tool 3 is further lowered, resulting in the state in FIG. 9B and then a state in which the attachment 2 is held as shown in FIG. 9C. However, the state shown in FIG. 9C is not suitable for a sliding operation since the lower wide portion 201 of the attachment 2 is in contact with the guide 41. In view of this, as shown in FIG. 9D, the height is adjusted so that neither the lower wide portion 201 nor the upper wide portion 202 makes contact with the guide 41.

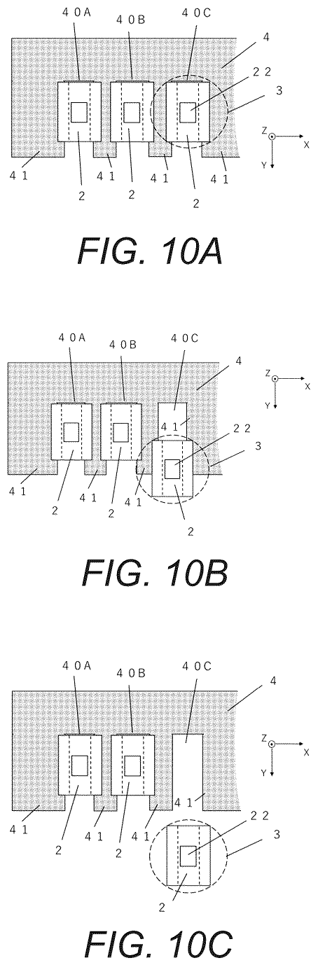

The attachment 2 can slide with respect to the guide 41 in the state shown in the front view of FIG. 9D, and FIGS. 10A, 10B and 10C are top views showing how the attachment 2 slides while its height is maintained.

FIG. 10A shows the state in which the slide operation is started. When the attachment storage unit 4 moves in the horizontal direction, the attachment 2 moves along the guide 41 (due to relative movement with respect to the attachment storage unit 4) outward from the storage unit 40C (FIG. 10B), and is removed from the storage space 40C as shown in FIG. 10C. In the state in FIG. 10C, the attachment 2 can move up and down, and the collet 21 can be used to pick up the chip component.

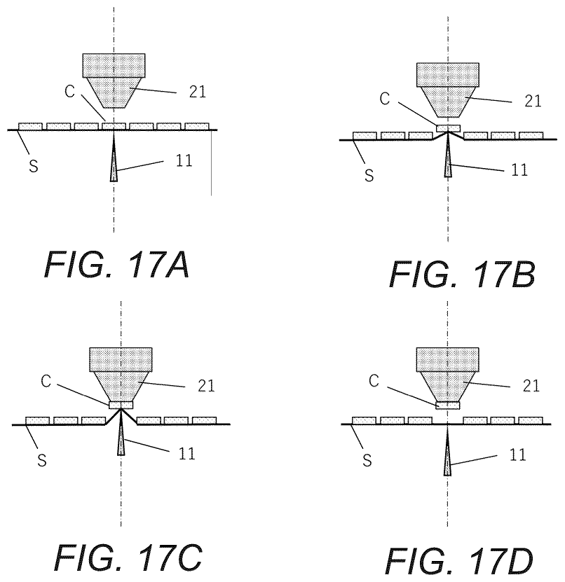

With the collet 21 of this embodiment, the attachment 2 is not allowed to come off from the attachment holder 31 when picking up the chip component C and transferring it to another place as shown in FIG. 17. Therefore, the force by which the attachment holder 31 magnetically holds the attachment 2 needs to be weak enough to release the attachment 2 from its state of being caught by the guide 41 as shown in FIGS. 6B and 6C, but the strength with which the attachment holder 31 holds the attachment 2 must be strong enough that the attachment 2 will not come off during pickup and transfer work. In addition, when the collet 21 holds the chip component C by suction, the force with which the attachment holder 31 holds the attachment 2 slightly increases in addition to the magnetic force due to the suction force produced by the reduced pressure.

Up to this point, the operation of storing the attachment 2 in the attachment storage unit 4 and the operation in which the pickup tool 3 removes the attachment 2 from the attachment storage unit 4 have been described, but these operations involve the movement of the attachment storage unit 4. Also, when the attachment storage unit 4 is provided on the wafer table 5 as shown in FIG. 3, vibration may be transmitted due to the operation of picking up the chip component. If the attachment storage unit 4 moves or vibrates, the attachment 2 that is supposed to be stored at a specific position in the storage space 40 may shift along the guide (in the sliding direction) and become detached from the end.

Therefore, it is preferable to provide a slide prevention means to prevent this displacement. An example of an anti-slide mechanism will now be described.

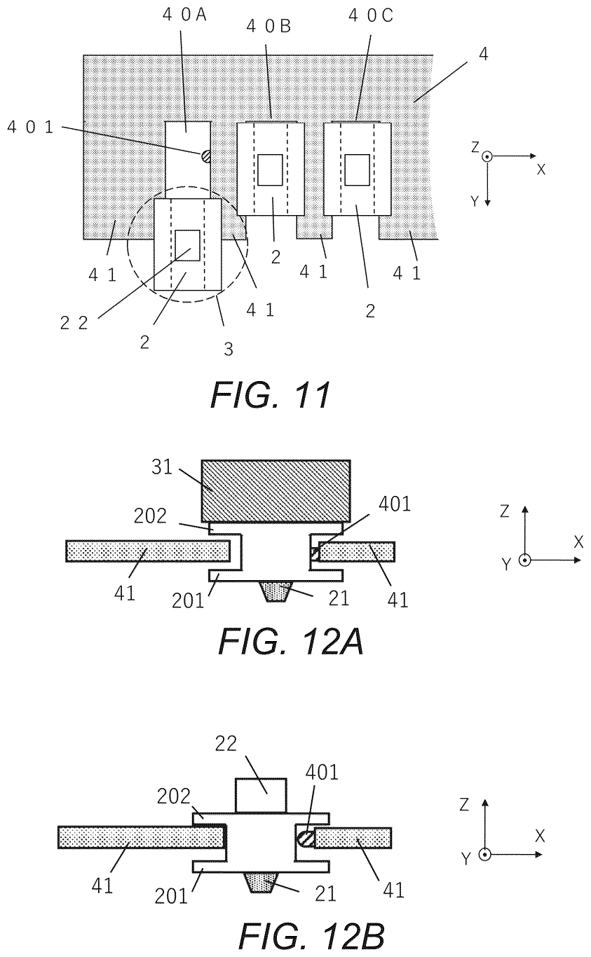

FIG. 11 is a top view showing an example in which an elastic body is used as a first example, and in which an elastic body 401 protruding toward the storage spaces 40 is provided to the guide 41 at a position corresponding to a specific position of the attachment 2. Here, the elastic body 401 is preferably flexible, and when the attachment 2 held by the pickup tool 3 slides, the elastic body 401 contracts as shown in the front view of FIG. 12A. Also, when the pickup tool 3 has been removed, the elastic body 401 exerts its elasticity to press the attachment 2 against the guide 41 on the opposite side, as shown in the front view of FIG. 12B, thereby suppressing displacement.

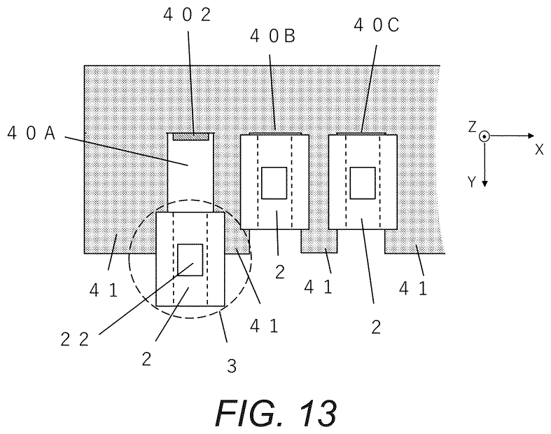

FIG. 13 is a top view showing a second example of the slide prevention means, in which magnets 402 are provided to the storage spaces 40. Using a magnetic material for the attachment main body 20 allows the position to be fixed by the magnet 402.

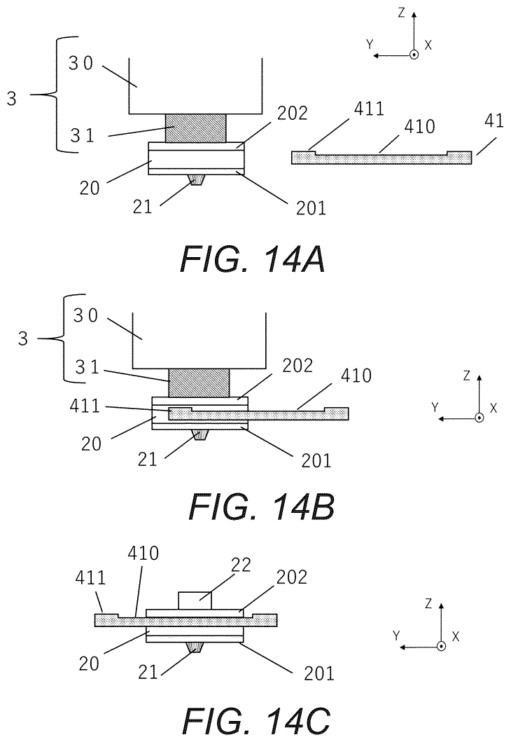

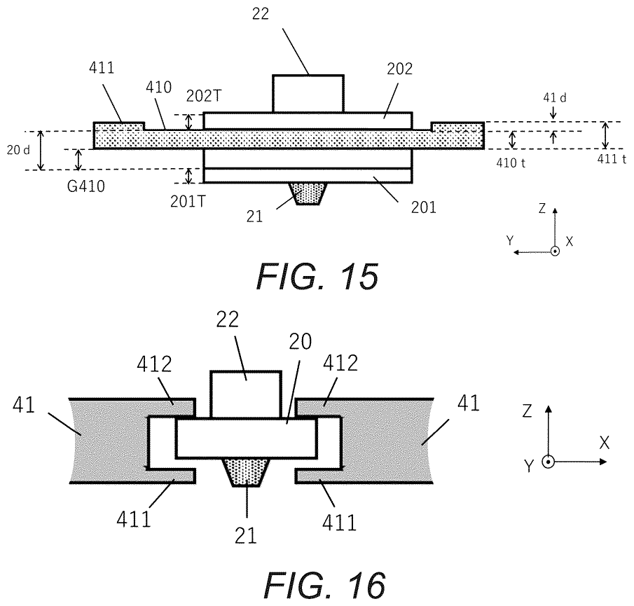

FIGS. 14A, 14B and 14C are side views illustrating a third example of the slide prevention means, which is characterized in that a groove, into which the upper wide portion 202 of the attachment 2 fits, is provided on the upper surface of the guide 41. That is, as shown in FIG. 14A, the guide 41 has a shape in which a thick guide portion 411 and a thin guide portion 410, which share a bottom surface, are provided. After the attachment 2 has been slid along the guide 41 with its height position adjusted as shown in FIG. 14B, the attachment 2 is removed from the pickup tool 3, resulting in the state shown in FIG. 14C. FIG. 15 is a detail side view of the state of FIG. 14C. In this state, the step 41d between the thin guide portion 410 and the thick guide portion 411 acts as a barrier against the upper wide portion 202 of the attachment 2, preventing the attachment 2 from coming off the guide 41.

Three examples were given above, but the slide prevention means is not limited to these, and two or more slide prevention means may be combined.

In the description up to this point, an example of the attachment 2 having the lower wide portion 201 and the upper wide portion 202 on the attachment main body 20 has been described, but the shape of the attachment 2 is not limited to this, and various shapes are possible by combining shapes of the guide 41 such that the attachment 2 will catch in the up and down direction when disposed in a storage space 40. For example, as shown in the front view of FIG. 16, the attachment main body 20 may not have the upper wide portion 202 and the lower wide portion 201, and instead the guide 41 may be provided with a lower wide portion 411 and an upper wide portion 412.

Also, the guides 41 do not necessarily have to be provided parallel to each other, in which case the attachment 2 does not have to be slid along the guides 41. For example, the guide 41 may have a shape that narrows moving deeper into the storage space 40. That is, the shape of the attachment main body 20 should be determined so that the attachment 2 is latched by the guide 41 according to the shape of the guide 41 and the storage space 40 of the attachment storage unit 4, and the attachment 2 may be detached from the attachment holder 31 while latched by the guide 41.

As described above, with the present disclosure, the attachment 2 can be easily replaced. Therefore, a collet can be easily replaced by providing a different collet 21 for each of a plurality of attachments 2.

In the description of the embodiments up to this point, the pickup tool 3 was said to be able to move in the up and down direction (and in the rotational direction around the up and down direction), but a function may be provided to allow the pickup tool 3 to move in the horizontal direction (in the XY plane), so that the pickup tool 3 is moved to be stored and removed in a state in which the attachment storage unit 4 is stopped.

1. A collet replacement mechanism for replacing a collet of a pickup tool that is configured to pick up chip components by suction using the collet, the collet replacement mechanism comprising:
an attachment configured to hold the collet on a bottom surface thereof;
an attachment holder disposed at a lower part of the pickup tool and holds the configured to hold an upper part of the attachment by magnetic force; and
an attachment storage unit having a guide that is configured to latch the attachment to store the attachment by latching it to a guide,
the attachment being detachable from the attachment holder in a state of being latched to the guide.

2. A collet replacement mechanism for replacing a collet of a pickup tool that is configured to pick up chip components by suction using the collet, the collet replacement mechanism comprising:
an attachment configured to hold the collet on a bottom surface thereof;
an attachment holder disposed at a lower part of the pickup tool and configured to hold an upper part of the attachment by magnetic force; and
an attachment storage unit having a guide that is configured to slidably store the attachment along the guide,
the attachment being detachable by being moved in a direction different from a sliding direction with respect to the guide of the attachment storage unit.

3. The collet replacement mechanism according to claim 1, wherein
the magnetic force with which the attachment holder holds the attachment is strong enough that the attachment does not come off the attachment holder when a chip component is picked up, and
the guide restricts a vertical movement of the attachment to remove the attachment from the attachment holder when the pickup tool being lifted up.

4. The collet replacement mechanism according to claim 1, wherein
the attachment storage unit is configured to suppress positional displacement of the attachment.

5. The collet replacement mechanism according to claim 4, wherein
the guide is provided with an elastic body that is configured to contact with a side surface of the attachment to suppress the positional displacement of the attachment.

6. The collet replacement mechanism according to claim 4, wherein
the attachment storage unit is provided with a magnet to suppress the positional displacement of the attachment.

7. The collet replacement mechanism according to claim 4, wherein
the guide is provided with a groove on an upper surface of the guide to suppress the positional displacement of the attachment.

8. The collet replacement mechanism according to claim 3, wherein
the attachment storage unit is configured to suppress positional displacement of the attachment.

9. The collet replacement mechanism according to claim 8, wherein
the guide is provided with an elastic body that is configured to contact with a side surface of the attachment to suppress the positional displacement of the attachment.

10. The collet replacement mechanism according to claim 8, wherein
the attachment storage unit is provided with a magnet to suppress the positional displacement of the attachment.

11. The collet replacement mechanism according to claim 8, wherein
the guide is provided with a groove on an upper surface of the guide to suppress the positional displacement of the attachment.

12. The collet replacement mechanism according to claim 2, wherein
the magnetic force with which the attachment holder holds the attachment is strong enough that the attachment does not come off the attachment holder when a chip component is picked up, and
the guide restricts a vertical movement of the attachment to remove the attachment from the attachment holder when the pickup tool being lifted up.

13. The collet replacement mechanism according to claim 2, wherein
the attachment storage unit is configured to suppress positional displacement of the attachment.

14. The collet replacement mechanism according to claim 13, wherein
the guide is provided with an elastic body that is configured to contact with a side surface of the attachment to suppress the positional displacement of the attachment.

15. The collet replacement mechanism according to claim 13, wherein
the attachment storage unit is provided with a magnet to suppress the positional displacement of the attachment.

16. The collet replacement mechanism according to claim 13, wherein
the guide is provided with a groove on an upper surface of the guide to suppress the positional displacement of the attachment.

17. The collet replacement mechanism according to claim 12, wherein
the attachment storage unit is configured to suppress positional displacement of the attachment.

18. The collet replacement mechanism according to claim 17, wherein
the guide is provided with an elastic body that is configured to contact with a side surface of the attachment to suppress the positional displacement of the attachment.

19. The collet replacement mechanism according to claim 17, wherein
the attachment storage unit is provided with a magnet to suppress the positional displacement of the attachment.

20. The collet replacement mechanism according to claim 17, wherein
the guide is provided with a groove on an upper surface of the guide to suppress the positional displacement of the attachment.
